(19) United States
(12) Patent Application Publication
(10) Pub. No.: US 2022/0196737 A1
(43) Pub. Date: Jun. 23, 2022

(54) TEST ASSISTANCE DEVICE, TEST ASSISTANCE METHOD AND STORAGE MEDIUM STORING PROGRAM

(71) Applicant: NEC Corporation, Tokyo (JP)

(72) Inventors: Kazuki TANABE, Tokyo (JP); Takayuki Kuroda, Tokyo (JP)

(73) Assignee: NEC Corporation, Tokyo (JP)

(21) Appl. No.: 17/547,486

(22) Filed: Dec. 10, 2021

(30) Foreign Application Priority Data
Dec. 22, 2020 (JP) 2020-212748

(51) Int. Cl. G01R 31/3181

(52) U.S. Cl. CPC G01R 31/31813; G06F 11/3688

(57) ABSTRACT

A test assistance device includes at least one memory configured to store instructions; and at least one processor configured to execute the instructions to; generate one or more of a test pattern in which a value of a parameter in test target-associated information is determined based on the test target-associated information indicating, so as to include the parameter, a requirement for a test defined in accordance with a test target, and generate a system requirement for a system satisfying the requirement for the test indicated by the test pattern.

This application is based upon and claims the benefit of priority from Japanese patent application No. 2020-212748, filed Dec. 22, 2020, the disclose of which is incorporated herein in its entirety by reference.

### TECHNICAL FIELD

The present invention relates to a test assistance device, a test assistance method and a storage medium storing a program.

### BACKGROUND ART

Non-Patent Document 1 (T. Kuroda, T. Kuwahara, T. Maruyama, K. Satoda, H. Shimonishi, T. Osaki, and K. Matsuda, “Weaver: a Novel Configuration Designer for IT/NW Services in Heterogeneous Environments”, Proceedings of IEEE GLOBECOM 2019, pp. 1-6, December 2019) describes technology for automatically designing systems. In the technology in Non-Patent Document 1, requirements for systems are input and system configurations satisfying the input requirements are generated and output. The input requirements for systems are described in combinations of multiple fundamental requirements, and the design is performed so as to generate system configurations satisfying the multiple requirements.

### SUMMARY

An example of an objective of the present invention is to provide a test assistance device, a test assistance method and a storage medium storing a program that can solve the above-described problem.

According to a first aspect of the present disclosure, a test assistance device includes test pattern generation means for generating one or more of a test pattern in which a value of a parameter in test target-associated information is determined based on the test target-associated information indicating, so as to include the parameter, a requirement for a test defined in accordance with a test target, and system requirement generation means for generating a system requirement for a system satisfying the requirement for the test indicated by the test pattern.

According to a second aspect of the present disclosure, a test assistance method involves generating one or more of a test pattern in which a value of a parameter in test target-associated information is determined based on the test target-associated information indicating, so as to include the parameter, a requirement for a test defined in accordance with a test target, and generating a system requirement for a system satisfying the requirement for the test indicated by the test pattern.

According to a third aspect of the present disclosure, a program stored in a storage medium makes a computer execute processes for generating one or more of a test pattern in which a value of a parameter in test target-associated information is determined based on the test target-associated information indicating, so as to include the parameter, a requirement for a test defined in accordance with a test target, and system requirement generation means for generating a system requirement for a system satisfying the requirement for the test indicated by the test pattern.

### BRIEF DESCRIPTION OF THE DRAWINGS

FIG. 1 is a schematic block diagram indicating the functional structure of a test assistance device according to a first embodiment.

FIG. 2 is a diagram indicating an example of the input and output of data in the test assistance device according to the first embodiment.

FIG. 3 is a diagram indicating an example of test target-associated information according to the first embodiment.

FIG. 4 is a diagram indicating an example of a test pattern set according to the first embodiment.

FIG. 5 is a diagram indicating a display example of a test pattern set according to the first embodiment.

FIG. 6 is a diagram indicating an example of system requirements according to the first embodiment.

FIG. 7 is a flow chart indicating an example of a processing procedure performed by the test assistance device according to the first embodiment.

FIG. 8 is a schematic block diagram indicating an example of the structure of a test assistance device according to a second embodiment.

FIG. 9 is a diagram indicating an example of the input and output of data in the test assistance device according to the second embodiment.

FIG. 10 is a diagram indicating an example of a system requirement template according to the second embodiment.

FIG. 11 is a diagram indicating an example of a refinement template according to the second embodiment.

FIG. 12 is a diagram indicating an example of a test environment according to the second embodiment.

FIG. 13 is a flow chart indicating an example of a processing procedure performed by the test assistance device according to the second embodiment.

FIG. 14 is a schematic block diagram indicating an example of the structure of a test assistance system according to a third embodiment.

FIG. 15 is a diagram indicating an example of the input and output of data in the test assistance system according to the third embodiment.

FIG. 16 is a diagram indicating an example of a test result set according to the third embodiment.

FIG. 17 is a flow chart indicating an example of a processing procedure performed by the test assistance system according to the third embodiment.

FIG. 18 is a diagram indicating an example of the structure of a test assistance device according to a fourth embodiment.

FIG. 19 is a flow chart indicating an example of a processing procedure in a test assistance method according to a fifth embodiment.

FIG. 20 is a schematic block diagram indicating the structure of a computer according to at least one embodiment.

### EXAMPLE EMBODIMENT

Hereinafter, the present embodiments will be described. However, the embodiments below do not limit the disclosure associated with the claims. Additionally, not all combinations of the features described in the embodiments are necessarily essential for the solution.

### First Embodiment

### (Description of Structure)

FIG. 1 is a schematic block diagram indicating the functional structure of a test assistance device according to a first embodiment. In the structure indicated in FIG. 1, the test assistance device 100 comprises a communication unit 110, a display unit 120, an operation input unit 130, a storage unit 180, and a control unit 190.

The control unit 190 comprises a test pattern generation unit 191 and a system requirement generation unit 192.

The test assistance device 100 assists in constructing a test environment for a test target.

The test target mentioned here may be various things that are tested in a system serving as a test environment, and is not limited to anything specific. For example, the test target may be a system or a device. Alternatively, the test target may be hardware, software, or a combination of hardware and software, used in a system or a device.

The test environment mentioned here is an operating environment for the test target. The test environment may be a system including the test target. Alternatively, the test environment may be a combination of a system including the test target and the surrounding environment. The surrounding environment of a system mentioned here may include conditions at the time that the system is operating, such as the room temperature or the humidity in a room in which the system is installed.

The system used as the test environment is not limited to being a specific type of system. For example, an ICT (Information Communication Technology) system may be used as the test environment, though there is no limitation thereto.

The test assistance device 100 may be configured by using a computer such as, for example, a personal computer (PC) or a workstation.

The test that is to be assisted by the test assistance device 100 may be various tests that are performed by constructing a system, and is not limited to anything specific. For example, the test to be assisted by the test assistance device 100 may be a performance test, or may be an operation checking test.

Hereinafter, the test that is assisted by the test assistance device 100 will also be referred to simply as the test.

The test assistance device 100 receives test target-associated information that is input and outputs a system requirement set.

The test target-associated information is information indicating requirements for tests defined in accordance with the test target. The test target-associated information indicates information required for evaluating the test target in an abstract form. The system requirement set is information including one or more system requirements. The system requirements are requirements for systems used as test environments, or information indicating those requirements. The requirements for systems mentioned here include processes such as measurements or determinations performed for the test, such as, for example, measurements of CPU usage.

In cases such as when the test target is an application program that operates on a system, tests are sometimes performed exhaustively using various systems as the test environment. In such cases, the test assistance device 100 can perform tests exhaustively using each of the multiple systems as test environments, by outputting system requirement sets including the system requirements for each of multiple systems.

Hereinafter, an example of the case in which the test target is a facial recognition application program and a facial recognition system is constructed as the test environment will be explained. However, as mentioned above, the test targets and the test environments handled by the test assistance device 100 are not limited to specific types.

Application programs will sometimes be referred to simply as applications.

The communication unit 110 communicates with other devices. For example, the communication unit 110 may transmit system requirement sets generated by the test assistance device 100, to a system design device for receiving system requirement inputs and automatically designing systems.

The display unit 120 comprises a display screen such as, for example, a liquid crystal panel or an LED (Light-Emitting Diode) panel, and displays various images. For example, the display unit 120 may display various types of information, such as system requirement sets generated by the test assistance device 100, in response to user operations.

The operation input unit 130 comprises an input device such as, for example, a keyboard and a mouse, and receives user operations. For example, when the user prepares test target-associated information, the operation input unit 130 may receive user operations for preparing the test target-associated information.

However, the method by which the test assistance device 100 acquires the test target-associated information is not limited to a method of preparation by a user. For example, a test target designer may prepare test target-associated information in accordance with the test target and register the information in a database, and the communication unit 110 may receive the test target-associated information from the database.

The storage unit 180 stores various types of information. The storage unit 180 is composed of a storage device provided in the test assistance device 100.

The control unit 190 controls the units in the test assistance device 100 to perform various types of processes. The functions of the test assistance device 100 are performed, for example, by a CPU (Central Processing Unit) in the test assistance device 100 reading a program from the storage unit 180 and executing the program.

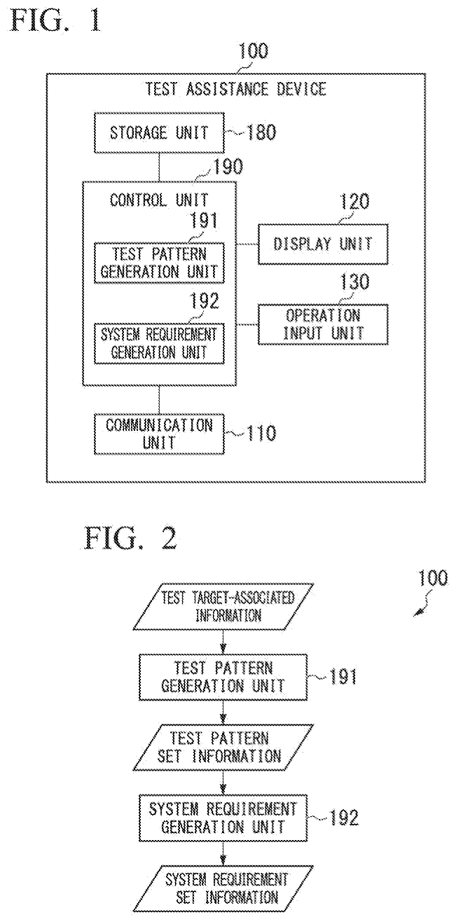

FIG. 2 is a diagram indicating an example of the input and output of data in the test assistance device 100.

The test pattern generation unit 191 receives test target-associated information that is input and outputs a test pattern set. The test pattern set is information including one or more test patterns. The test patterns are information indicating requirements for a test performed in each test environment.

Specifically, the test pattern generation unit 191 acquires test target-associated information that indicates requirements, including parameters, for tests defined in accordance with a test target. Furthermore, the test pattern generation unit 191 generates each test pattern by determining values for the parameters in the test target-associated information.

The parameters mentioned here may be considered to be possible variables for the requirements employed when testing the test target. The same applies in the embodiments below.

For example, the test pattern generation unit 191 selects any of multiple options for the values of parameters in the test target-associated information. The test pattern generation unit 191 corresponds to an example of a test pattern generation means.

The system requirement generation unit 192 receives a test pattern set that is input and outputs a system requirement set. Specifically, the system requirement generation unit 192 receives, as an input, a test pattern set generated by the test pattern generation unit 191, and generates system requirements for each test pattern included in the test pattern set. The system requirement generation unit 192 generates and outputs a system requirement set in which the generated system requirements are organized.

The system requirement generation unit 192 may, for example, generate data including only the data in a header of the system requirement set as the initial data in a system requirement set. Then, each time system requirements are generated, the system requirement generation unit 192 may add the system requirements to the system requirement set, thereby generating a system requirement set in which the system requirements are organized.

The system requirement generation unit 192 corresponds to an example of a system requirement generation means.

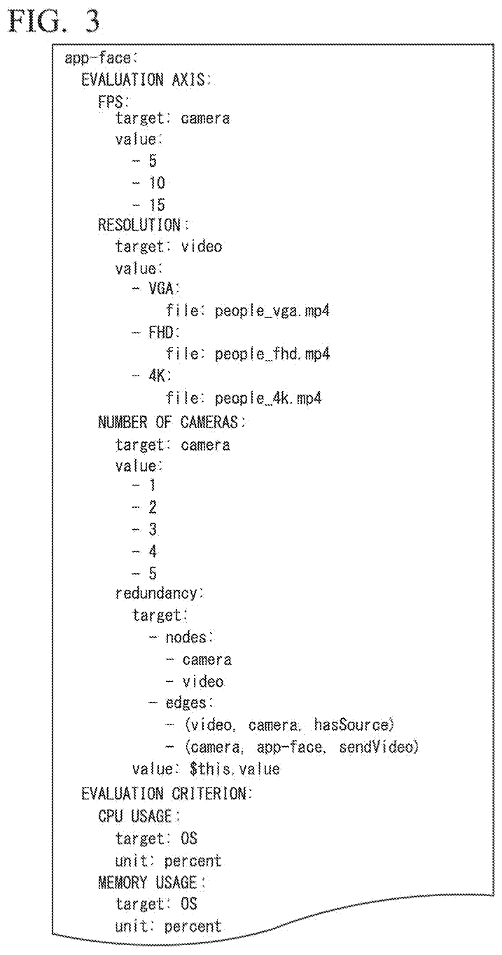

FIG. 3 is a diagram indicating an example of test target-associated information. In the example in FIG. 3, product data for a facial recognition application product named “app-face”, which is the test target, is indicated as being the test target-associated information.

In the example in FIG. 3, the test target-associated information includes a test target ID (identifier), one or more evaluation axes, and one or more evaluation criteria.

### (Test Target ID)

The test target ID is identification information for identifying a test target. In the example in FIG. 3, the test target ID “app-face” identifies the facial recognition application product “app-face”, which is the test target.

For example, the storage unit 180 may store test target-associated information for each of multiple test targets. In this case, the test pattern generation unit 191 can use the test target ID to read test target-associated information corresponding to the test target from the storage unit 180.

### (Evaluation Axes)

The evaluation axes provide information indicating variations (options) in a test.

In the example in FIG. 3, the test target-associated information includes the three evaluation axes “FPS”, “resolution”, and “number of cameras”. Each evaluation axis indicates variations in the test.

The evaluation axis “FPS” indicates the frame rate (FPS: frames per second) of a camera. In the evaluation axis “FPS”, the target criterion “camera”, which is indicated by the label “target”, indicates that “FPS” applies to a camera. The values “5”, “10”, and “15” indicated by the label “value:” indicate frame rate options.

The evaluation axis “resolution” indicates a test video projected on a camera. The target criterion “video” for the evaluation axis “resolution” indicates that the “resolution” applies to videos. The values “VGA: file: people_vga.mp4”, “FHD: file: people_fhd.mp4”, and “4K: file: people_4k.mp4” on the evaluation axis “resolution” indicate options for the video format (such as the resolution) and the file names thereof

The evaluation axis “number of cameras” indicates options for the number of cameras, information regarding the cameras, video files that requires additionally deployed in accordance with that number, and the connection configurations for these elements. The target criterion “camera” on the evaluation axis “number of cameras” indicates that “number of cameras” applies to cameras. The values “1”, . . . , “5” on the evaluation axis “number of cameras” indicate options for the number of cameras.

Redundancy information, which is indicated by the label “redundancy”, indicates options regarding the relationships between the cameras and the videos indicated by the label “nodes:”.

Thus, in addition to the list of values indicated by the label “value:” and the information regarding the elements in the test environment to which the values indicated by the label “target” apply, the evaluation axis may include information, such as file configurations or network configurations, within the range affecting the test environment based on the values thereof.

A collection of evaluation axes will also be referred to as an evaluation axis set. An evaluation axis set can be considered to be a parameter set constituting variations to a test. In the example in FIG. 3, the collection of the three evaluation axes “FPS”, “resolution”, and “number of cameras” corresponds to an example of an evaluation axis set.

### (Evaluation Criteria)

The evaluation criteria are criteria to be evaluated by the test, or information indicating those criteria. The evaluation mentioned here may, for example, involve determining a quantitative or qualitative evaluation value by means of measurement, calculation, assessment, or the like.

In the example in FIG. 3, the two evaluation criteria “CPU usage” and “memory usage” are shown, relating to the CPU usage and the memory usage, representing the loads placed on the computer by the OS (operating system) on which the application program that is the test target is running

A collection of evaluation criteria will also be referred to as an evaluation criterion set. In the example in FIG. 3, the collection of the two evaluation criteria “CPU usage” and “memory usage” corresponds to an example of an evaluation criterion set. The target criterion “OS” in each evaluation criterion indicates that the evaluation applies to an OS. The unit “percent” indicated by the label “unit:” indicates that the evaluation value is to be represented by a percentage.

The specific content of the test target-associated information is not limited to that in the example indicated in FIG. 3.

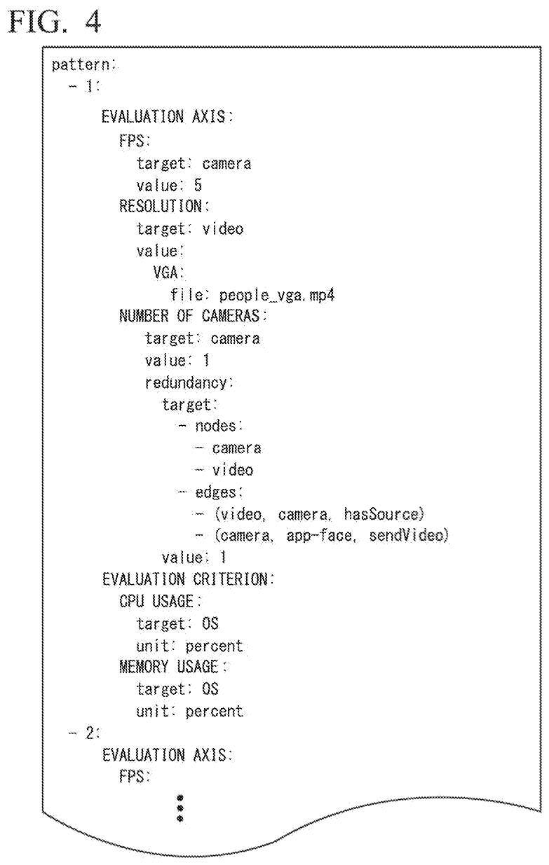

FIG. 4 is a diagram indicating an example of a test pattern set. The test pattern set includes one or more test patterns. In the example in FIG. 4, the labels “1:”, “2:”, . . . indicate each test pattern.

One test pattern includes the values of an evaluation axis set indicating the requirements for one system serving as a test environment, and an evaluation criterion set for a test using that test environment. The test pattern indicates the requirements for one system by determining the values on the respective evaluation axes included in the evaluation axis set. As mentioned above, the test pattern generation unit 191 generates one test pattern by determining values on the respective evaluation axes in the test target-associated information.

An evaluation axis for which the value is not uniquely determined may be considered to be equivalent to a parameter. Determining a value on the evaluation axis may be considered to be equivalent to determining the value of a parameter.

For example, the test pattern indicated by the label “1:” in the example in FIG. 4 is obtained by determining the value on the evaluation axis “FPS” to be “5”, determining the value on the evaluation axis “resolution” to be “VGA: file: people_vga.mp4”, and determining the value on the evaluation axis “number of cameras” to be “1” in the test target-associated information in FIG. 3.

The evaluation axis “resolution” in this test pattern indicates that “people_vga.mp4” should be uploaded and played as the video file. Additionally, the evaluation axis “number of cameras” indicates that one each of the camera and the video file are provided, the video file is projected on the camera, and video images from the camera are transmitted to the application “app-face”.

The method by which the test pattern generation unit 191 determines the values on the evaluation axes in the test target-associated information is not limited to a specific method. For example, the test pattern generation unit 191 may generate a test pattern for each possible combination of values on the evaluation axes. Alternatively, the test pattern generation unit 191 may select values randomly from among the options for the values on the evaluation axes. Alternatively, the test pattern generation unit 191 may display options or ranges of values on the evaluation axes on the display unit 120, and the values on the evaluation axes may be determined in accordance with user operations for designating values.

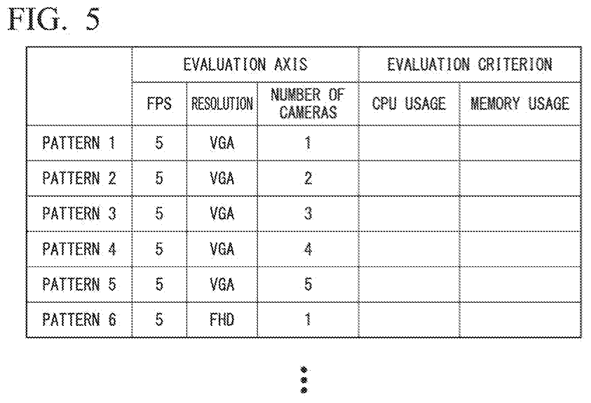

FIG. 5 is a diagram indicating an example of the display of a test pattern set.

FIG. 5 indicates an example in which the test pattern set indicated in FIG. 4 is displayed in table form. In the display form in FIG. 5, the abstract information for constructing evaluation requirements associated with each evaluation axis, and the information regarding the evaluation target and information regarding the form (units) of the values for each evaluation criterion are omitted for the sake of simplicity.

The specific content and the form of display of the test pattern set are not limited to the examples indicated in FIG. 4 and FIG. 5.

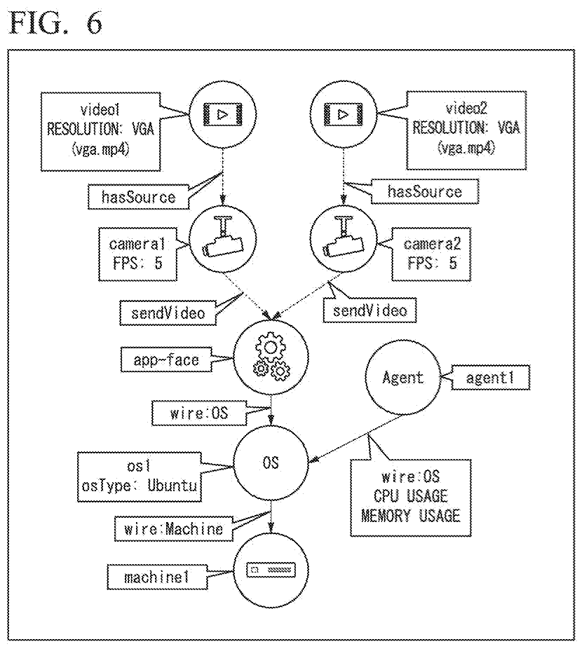

FIG. 6 is a diagram indicating examples of system requirements. FIG. 6 shows an example in which the display unit 120 displays one example of the system requirements in the form of a graph. Specifically, a test pattern is indicated by a graph structure in which system elements are represented by nodes and the connection relationships between elements are represented by edges. The system requirements indicate, in an abstract manner, the elements required for constructing systems serving as test environments. For example, by refining the system requirements in units of the elements, system configurations refined to deployable levels can be designed.

Additionally, in the example in FIG. 6, attribute value information is added to some of the nodes and edges.

For example, the fact that the application “app-face” runs on a server using the Ubuntu Linux (Ubuntu and Linux are both registered trademarks) as OS is indicated by the attribute information in the nodes and edges. Specifically, as an attribute value for the “OS” node, an OS type is indicated. Furthermore, the connection relationship from the “app-face” node to the OS1 node is represented by a “wire: OS” edge, and the connection relationship from the OS1 node to the “machinel” node is represented by a “wire: Machine” edge. The “wire: OS” edge indicates a connection between an application and an OS. The “wire: Machine” edge indicates a connection between an OS and a server.

Additionally, a “cameral” node and a “camera2” node, which are nodes representing cameras, are connected from video type nodes, representing video files, by hasSource edges, which represent that those nodes are the projection sources of the videos. As video type nodes, a “video1” node and a “video2” node are provided.

In the example in FIG. 6, the connection relationship connecting each of the “camera1” node and the “camera2” node to the “app-face” node with a “sendVideo” edge is indicated by the text regarding the evaluation axis “number of cameras” in the test pattern indicated in FIG. 4.

Specifically, the text “(Video, Camera, hasSource)” in “edges:” regarding the “number of cameras” in the test pattern indicates that the “Video” nodes and the “Camera” nodes are connected by “hasSource” edges. Additionally, the entry for “value:” regarding “redundancy” indicates the number of cameras connected to the “app-face” node.

FIG. 6 indicates an example of the case in which the value “value:” of the redundancy “redundancy” is “2”. Based on this value, the system requirement generation unit 192 provides the “Camera1” node and the “Camera2” node, which are two “Camera” nodes, and connects each of the nodes to the “app-face” node by a “sendVideo” edge.

Regarding the method for acquiring the CPU usage and the memory usage, which are the evaluation criteria, these two evaluation criteria are added to the “wire: OS edge” from the “Agent1” node, which is the subject that executes the evaluation program, to the “OS1” node. As a result thereof, it is expressed that the “Agent1” node executes the evaluation program on the “OS1” node.

An arrow on a solid line represents an edge with a specific connection relationship. An arrow on a dashed line represents an edge with an abstract connection relationship. The specific content and display forms of the evaluation requirements are not limited to those in the example indicated in FIG. 6.

### (Description of Operations)

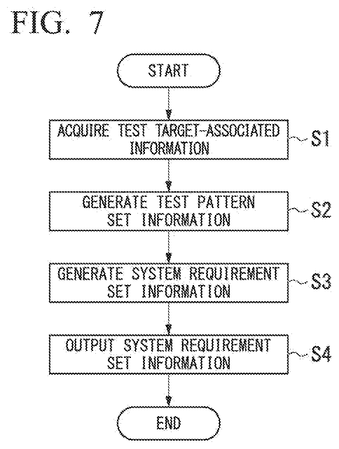

FIG. 7 is a flow chart indicating an example of the processing procedure performed by the test assistance device 100. In the process in FIG. 7, the test pattern generation unit 191 acquires test target-associated information (step S1).

Furthermore, the test pattern generation unit 191 generates a test pattern set based on information regarding the evaluation axis set and information regarding the evaluation criterion set included in the acquired test target-associated information (step S2). Specifically, the test pattern generation unit 191 generates one test pattern by determining the values on the respective evaluation axes in the evaluation axis set included in the test target-associated information. For example, the test pattern generation unit 191 repeatedly generates test patterns for all combinations of values in the evaluation axis set, and organizes the resulting test patterns in a test pattern set.

The test pattern generation unit 191 may, for example, generate data including only data for the header of a test pattern set as the initial data in a test pattern set. Then, each time a test pattern is generated, the test pattern generation unit 191 may add the test pattern to the test pattern set, thereby generating a test pattern set in which the test patterns are organized.

Next, the system requirement generation unit 192 generates a system requirement set based on the test pattern set generated by the test pattern generation unit 191 in step S2 (step S3). Specifically, the system requirement generation unit 192 generates system requirements for each test pattern included in the test pattern set, and organizes the obtained system requirements in a system requirement set.

Then, the system requirement generation unit 192 outputs the system requirement set generated in step S3 (step S4). For example, the system requirement generation unit 192 may transmit the generated system requirement set to an automated system design device via the communication unit 110.

After step S4, the test assistance device 100 ends the process in FIG. 7.

Thus, with the test assistance device 100, the test pattern generation unit 191 generates a test pattern set on the basis of the information regarding the evaluation axis set and the information regarding the evaluation criterion set indicated in the test target-associated information. Then, the system requirement generation unit 192 generates and outputs a system requirement set corresponding to the test pattern set.

### (Description of Effects)

As described above, the test pattern generation unit 191 generates one or more test patterns in which the values of parameters in test target-associated information are determined based on the test target-associated information that indicates requirements, including parameters, for tests defined in accordance with a test target. The system requirement generation unit 192 generates system requirements for systems satisfying the requirements for the tests indicated by test patterns generated by the test pattern generation unit 191.

Thus, the test assistance device 100 generates a test pattern set and a system requirement set corresponding thereto from information regarding the evaluation axis set and the evaluation criterion set indicated in the test target-associated information that has been input. As a result thereof, the test assistance device 100 can automatically or semi-automatically determine one or more system requirements (define requirements) for an exhaustive test environment set (one or more test environments) that is required in the process of testing a test target, such as a product. According to the test assistance device 100, systems satisfying the requirements for a test can be generated relatively easily due to this feature.

Additionally, the test target-associated information includes an evaluation axis set indicating requirements for test environments for a test, selectable so as to include parameters, and the evaluation criterion set for the test.

As a result thereof, the test pattern generation unit 191 can generate test patterns by determining the values of the parameters included in the test target-associated information.

There are cases in which a test is performed by a test target in each of multiple test environments. For example, when developing a product such as an application or hardware that is an element constituting an ICT system, it is required that evaluation tests be performed exhaustively in system environments with various configurations in order to verify that the product satisfies the functional requirements and non-functional requirements in the environments in which users use the product. As examples of such tests, for application products, there are load tests for computers in which the applications are run, and for network device products, there are performance measurement tests, such as effective throughput tests.

When performing tests in each of multiple test environments in this way, there is a need to design and construct the system for each test environment, which presents a large burden in terms of man-hours required by workers. In particular, among the elements in a system serving as a test environment, the specific configurations such as those of a network or files will differ for each test. If the details of the system configuration information used in each test are to be predetermined manually, then the system configuration information used in a certain test will not be able to be reused in another test, and the amount of programming involved becomes enormous. On the other hand, if the system configuration information is determined in an abstract manner, then there is a need to refine the abstract elements and to define requirements for each test. Thus, in either case, manual work is required, and a large burden is placed on the workers.

In contrast therewith, according to the test assistance device 100, the requirements can be defined automatically or semi-automatically, as mentioned above, thereby reducing the burden on workers. In particular, the test pattern generation unit 191 generates test patterns for all combinations of values on the evaluation axes included in the test target-associated information. Thus, the system requirement generation unit 192 can exhaustively and automatically generate system requirements indicating the requirements for systems serving as test environments.

### Second Embodiment

### (Description of Structure)

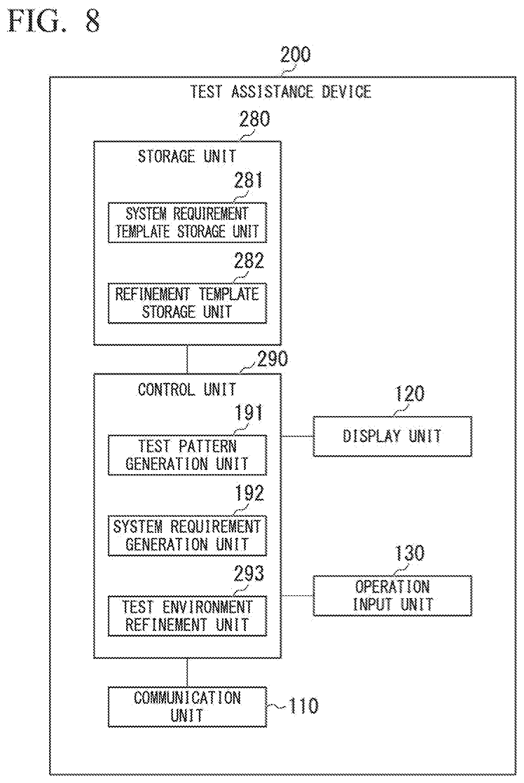

FIG. 8 is a schematic block diagram indicating an example of the structure of a test assistance device according to a second embodiment. In the structure indicated in FIG. 8, the test assistance device 200 comprises a storage unit 280 and a control unit 290. The storage unit 280 comprises a system requirement template storage unit 281 and a refinement template storage unit 282. The control unit 290 comprises a test environment refinement unit 293.

Among the parts indicated in FIG. 8, those corresponding to and having functions similar to those indicated in FIG. 1 will be assigned the same reference numbers (110, 120, 130, 191, and 192) and detailed descriptions thereof will be omitted here.

The structure of the test assistance device 200 indicated in FIG. 8 differs from that of the test assistance device 100 indicated in FIG. 1 in that the storage unit 280 comprises a system requirement template storage unit 281 and a refinement template storage unit 282, and in that the control unit 290 comprises a test environment refinement unit 293. Additionally, the process in the system requirement generation unit 192 in the second embodiment corresponds to a specific example of the process described for the first embodiment.

Aside therefrom, the test assistance device 200 is similar to the test assistance device 100.

The system requirement template storage unit 281 stores a system requirement template for each product. A system requirement template is information indicating a method for generating system requirements in response to the input of a test pattern. A system requirement template indicates, as parameters, information in the system requirements corresponding to evaluation axes in the test target-associated information. The system requirement generation unit 192 generates the system requirements by determining the values of these parameters to be the values indicated in the test pattern.

The refinement template storage unit 282 stores refinement templates. A refinement template is information indicating a refinement method for partially, or in steps, replacing a system configuration including abstract parts, such as system requirements, with specific configurations. Each item of information indicating this refinement method will be referred to as a refinement rule. Information including all refinement rules used in at least one system design (refinement) will be referred to as a refinement template.

The test environment refinement unit 293 designs, for each of the system requirements generated by the system requirement generation unit 192, a system configuration satisfying that system requirement. Specifically, the test environment refinement unit 293 repeatedly refines the system requirements using refinement rules. As a result thereof, the test environment refinement unit 293 converts system requirements to system configurations that are refined to a deployable level.

The test environment refinement unit 293 corresponds to an example of a test environment refinement means.

The system configuration mentioned here is the configuration of a system used as a system environment, or information indicating such a configuration. The system configuration and the system requirements differ in terms of the degree of refinement of the requirements or configuration of the system. The information generated by the system requirement generation unit 192 will be referred to as system requirements, and information indicating a system in which the requirements or the configuration are refined more than the system requirements will be referred to as a system configuration.

A system configuration set is information including one or more system configurations.

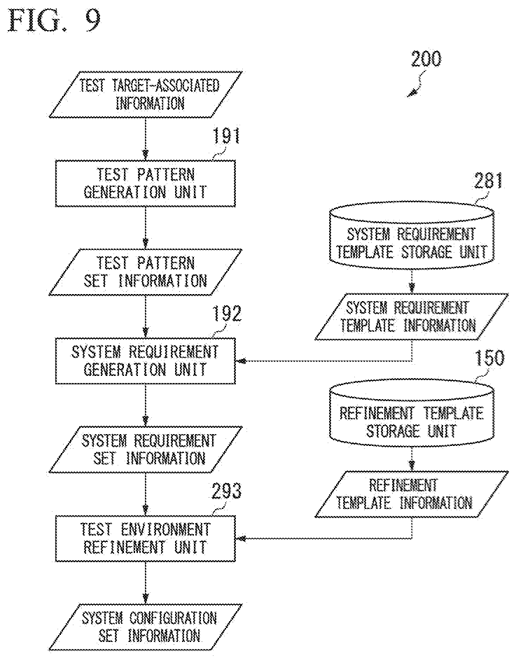

FIG. 9 is a diagram indicating an example of the input and output of data in the test assistance device 200.

The input and output of data in the test pattern generation unit 191 is similar to that in the case of FIG. 2. The system requirement generation unit 192 receives a test pattern set that is input, and outputs a system requirement set. In the example in FIG. 9, the system requirement generation unit 192 reads a system requirement template corresponding to the test target from the system requirement template storage unit 281. Then, the system requirement generation unit 192 generates system requirements for each test pattern by determining the values of parameters included in the system requirement template to be the values indicated by the test pattern. The system requirement generation unit 192 generates system requirements for all test patterns included in the test pattern set, and organizes the resulting system requirements in a system requirement set.

As mentioned above, the system requirements may be organized in a system requirement set by the system requirement generation unit 192 generating initial data for the system requirement set and adding system requirements to the system requirement set each time system requirement is generated.

The test environment refinement unit 293 receives a system requirement set that is input and outputs a system configuration set. Specifically, the test environment refinement unit 293 detects, for each of the system requirements generated by the system requirement generation unit 192, the system requirements, or in a system configuration in which refinement rules have been applied to the system requirements, the portions to which the refinement rules are applicable. The portions to which the refinement rules are applicable are portions that have matching refinement rules. Then, the test environment refinement unit 293 applies the refinement rules to the detected portions to perform partial refinement. The test environment refinement unit 293 performs repeated refinement using the refinement rules until a system configuration of a deployable level is obtained.

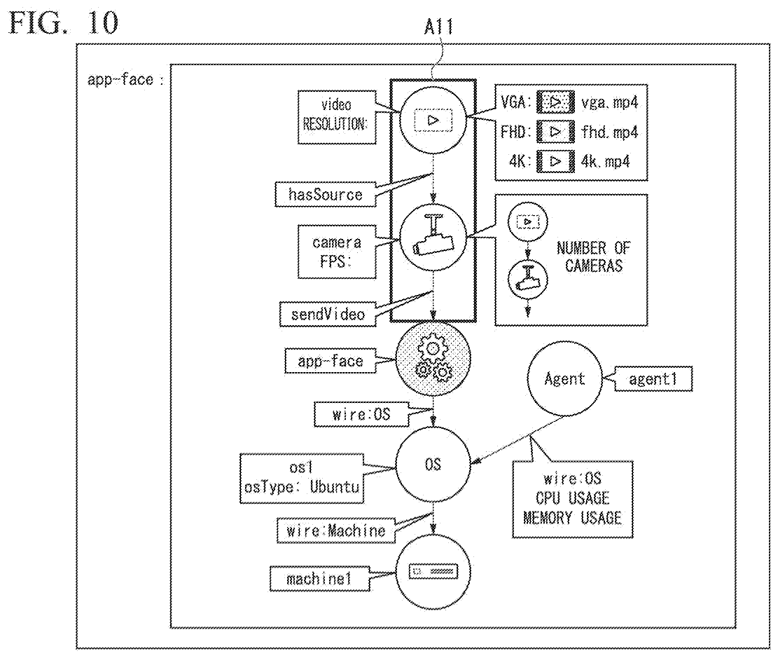

FIG. 10 is a diagram indicating an example of a system requirement template. FIG. 10 shows an example in which the display unit 120 displays an example of the system requirement template in the form of a graph.

FIG. 10 shows a system requirement template corresponding to the test target-associated information in FIG. 2. The system requirement template in FIG. 10 indicates a method for generating system requirements in accordance with a test pattern obtained from the test target-associated information in FIG. 2, such as the test pattern indicated in FIG. 4. Specifically, the system requirement generation unit 192 generates system requirements by determining the values of parameters included in the system requirement template to be the values indicated by the test pattern.

The system requirement template is expressed in the form of a graph similar to the system requirements indicated in FIG. 6. As in the case of the system requirements, attribute value information may be added to some of the nodes and edges in the system requirement template. Additionally, unlike in the case of the system requirements, parameters on the evaluation axes can be further added, as attribute value information, to the nodes in the system requirement template.

Additionally, the system requirement template indicates a method for partially substituting graphs in accordance with values on each of the evaluation axes. For example, in the system requirement template for the application product “app-face” indicated in FIG. 10, file names corresponding to each value on the “resolution” evaluation axis are indicated as a method for substituting a “video” node representing the video projected on a camera.

For example, if the value of the parameter on the “resolution” evaluation axis is determined to be “VGA”, then the system requirement generation unit 192 sets the attribute value information in the “video” node so as to upload the file “vga.mp4”. Alternatively, if the value of the parameter on the “resolution” evaluation axis is determined to be “FHD”, then the system requirement generation unit 192 sets the attribute value information in the “video” node so as to upload the file “fhd.mp4”. Alternatively, if the value of the parameter on the “resolution” evaluation axis is determined to be “3K”, then the system requirement generation unit 192 sets the attribute value information in the “video” node so as to upload the file “4k.mp4”.

After the attribute value information in the “video” node has been set, the system requirement generation unit 192 provides sub-graphs in the All portion in a number in accordance with the value on the “number of cameras” evaluation axis. The sub-graphs in the All portion are sub-graphs with a “camera” node, a “video node”, a “hasSource” edge connecting these, and a “sendVideo” edge connecting the “camera” node with the “app-face” node.

The fact that the “agent1” node makes the “os1” node perform evaluations for the evaluation criterion set with “CPU usage” and “memory usage” is indicated by attribute values added to a “wire: OS” edge connecting these nodes.

FIG. 11 is a diagram indicating an example of a refinement template. FIG. 11 shows an example in which the display unit 120 displays an example of the refinement template in the form of a graph.

Refinement rule T11 indicates a method for refining an abstract HTTP edge representing HTTP (HyperText Transfer Protocol) communication between applications. Under this refinement rule, the test environment refinement unit 293 hosts application type nodes “appl” and “app2”, which are the endpoints of the HTTP edge, respectively, on the OS type nodes “os1” and “os2”, and connects the nodes with wire: OS edges. Furthermore, the test environment refinement unit 293 connects the two OS type nodes “os1” and “os2” with a TCP edge representing a TCP (Transmission Control Protocol) connection.

Refinement rule T12 indicates a method for refining the OS type node “os1”. Under this refinement rule, the test environment refinement unit 293 adds a machine type node representing the server for running the OS, the “os1” node and the added node being connected by a wire: OS edge.

Refinement rule T13 indicates a method for refining the machine type node “machine1”. Under this refinement rule, the test environment refinement unit 293 adds a router type node “router” representing a router, the “machine1” node and the “router” node being connected by a “wire: router” edge.

The test environment refinement unit 293 successively repeats the refinement of the system requirements using the refinement rules until there are no more abstract elements in the graph structures that are to be refined. That is, the test environment refinement unit 293 repeatedly refines the system requirements or the system configuration until a system configuration that has been refined to a deployable level is obtained.

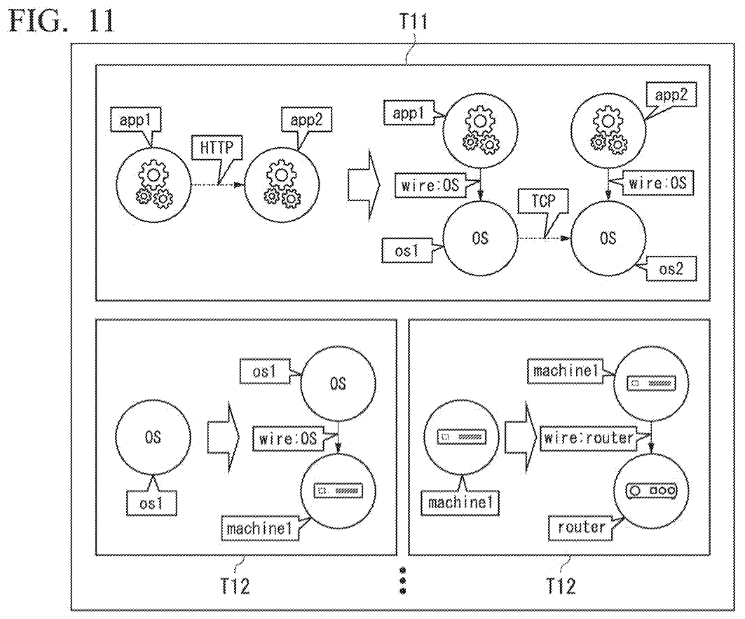

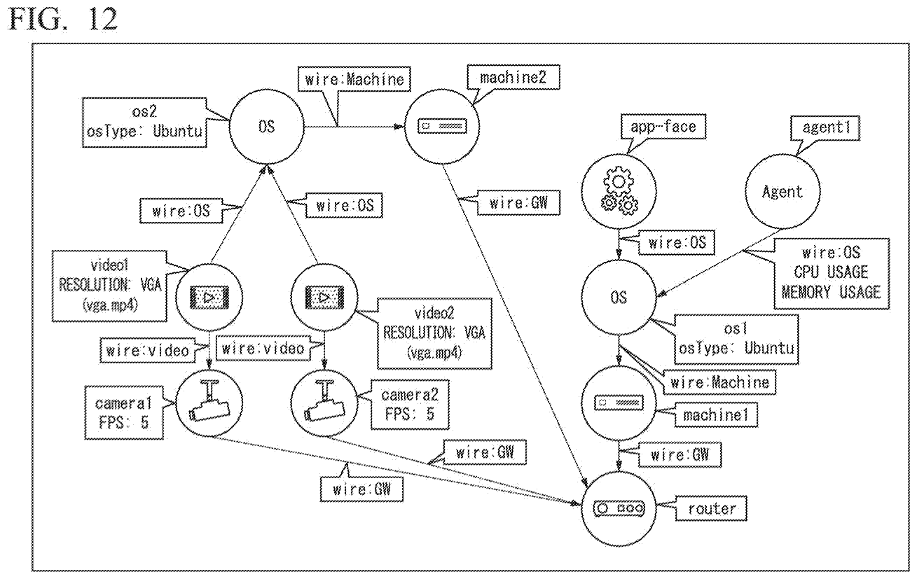

FIG. 12 is a diagram indicating an example of a test environment. FIG. 10 shows an example in which the display unit 120 displays, in the form of a graph, one example of a system configuration that has been refined to a level deployable as a test environment. Thus, the test environment mentioned here is information representing a specific configuration of the system that is required for performing a test on a test target such as a product. The test environment mentioned here includes a network configuration including the connection relationship between servers, a router and the like, as well as OS's and applications running on the servers, and detailed information such as file arrangements.

In the test environment indicated in FIG. 12, a “sendVideo” edge and a “hasSource” edge, which were abstract elements in the system requirements indicated in FIG. 5, are refined. Additionally, a “machine1” node, which is a server, and two camera nodes are connected to a “router” node, which is the same router. Furthermore, an “os2” node, which is an OS for playing the video files “video1” and “video2”, and a “machine2” node, which is a server on which that OS runs, are additionally deployed, and connected to the “router” node by a “wire: GW” edge.

Furthermore, in the example in FIG. 12, the type of evaluation test to be performed in the test environment, and the test target and the subject performing the evaluation test, are defined. In the example in FIG. 12, the fact that the “agent1” node makes the “os1” node perform evaluations for the evaluation criterion set with “CPU usage” and “memory usage” is indicated by an attribute value for the edge.

The specific content and display form of the system configuration indicating the test environment are not limited to those in the example indicated in FIG. 12.

### (Description of Operations)

FIG. 13 is a flow chart indicating an example of the processing procedure performed by the test assistance device 200. Among the processing steps in FIG. 13, those that are similar to processing steps in FIG. 7 will be assigned the same reference numbers (S1, S2) and detailed descriptions thereof will be omitted here.

Steps S1 and S2 in FIG. 13 are similar to those for the case in FIG. 7. After step S2, the system requirement generation unit 192 refers to the system requirement template storage unit 281 and acquires a system requirement template corresponding to the test target (step S11).

Then, the system requirement generation unit 192 generates a system requirement set based on the test pattern set generated in step S2 and the system requirement template acquired in step S11 (step S12). Specifically, for each test pattern included in the test pattern set, the system requirement generation unit 192 generates system requirements corresponding to that test pattern and organizes the generated system requirements into a system requirement set.

Next, the test environment refinement unit 293 refers to the refinement template storage unit 282 and acquires a refinement template corresponding to a test target such as a product (step S13).

Then, the test environment refinement unit 293 uses the system requirement set generated in step S12 and the refinement template acquired in step S13 to generate a system requirement set (step S14). Specifically, the test environment refinement unit 293 generates system configurations by refinement using the refinement rules for each of the system requirements included in the system requirement set. Then, the test environment refinement unit 293 organizes the generated system configurations in a system configuration set.

Then, the test environment refinement unit 293 outputs the generated system configuration set (step S15).

After step S15, the test assistance device 200 ends the process in FIG. 13.

Thus, in the test assistance device 200, the test pattern generation unit 191 generates a test pattern set based on evaluation axis set information and evaluation criterion set information indicated in the test target-associated information. Then, the system requirement generation unit 192 generates a system requirement set corresponding to the test pattern set based on the system requirement template acquired from the system requirement template storage unit 281. The test environment refinement unit 293 reads a refinement template from the refinement template storage unit 282 and uses refinement rules to refine each of the system requirements included in the system requirement set. As a result thereof, the test environment refinement unit 293 generates and outputs a system configuration set, as a test environment set, corresponding to the system requirement set.

### (Description of Effects)

As described above, the system requirement generation unit 192 generates one or more system requirements by determining the values of parameters in a system requirement template in which some of the system requirements among the system requirements are indicated by parameters.

As a result thereof, the system requirement generation unit 192 can generate a system requirement template by a relatively simple process of determining the values of the parameters in the system requirement template on the basis of test patterns. Additionally, the test assistance device 200 can automatically or semi-automatically determine one or more system requirements (define requirements) as an exhaustive test environment set that is required in the process of testing a test target, such as a product. According to the test assistance device 200, systems satisfying the requirements for tests can be generated relatively easily due to this feature.

Additionally, the test environment refinement unit 293 generates a system configuration satisfying system requirements by refining the system requirements.

As a result thereof, the test environment refinement unit 293 can automatically design a specific system configuration as a test environment based on the system requirements. According to the test environment refinement unit 293, the burden on workers can be reduced due to this feature.

Additionally, the test environment refinement unit 293 generates system configurations by repeatedly performing partial refinement of system requirements.

Thus, the test environment refinement unit 293 can automatically design specific system configurations as test environments by repeatedly refining the system requirements. According to the test environment refinement unit 293, the burden on workers can be reduced due to this feature.

Thus, according to the test assistance device 200, in addition to the effects described for the test assistance device 100, an exhaustive test environment set can be automatically generated, without involving manual work, by refining each of the system requirements in the test environment refinement unit 293.

Furthermore, in the test assistance device 200, when automatically generating test environments from test target-associated information, a method for generating a system requirement set based on the test target-associated information is indicated as a system requirement template. Additionally, in the test assistance device 200, the method used for refinement from system requirements to a test environment is indicated as a refinement template. Thus, when using the test assistance device 200 to construct test environments for a new test target, an engineer such as a user of the test assistance device 200 can refer to an existing refinement template to relatively easily generate a refinement template for the new test target.

The test assistance device 100 may comprise a refinement template storage unit 282 and a test environment refinement unit 293. As a result thereof, as in the case of the test assistance device 200, the test environment refinement unit 293 can automatically generate, from a system requirement set, a system configuration set as a test environment set.

### Third Embodiment

### (Description of Structure)

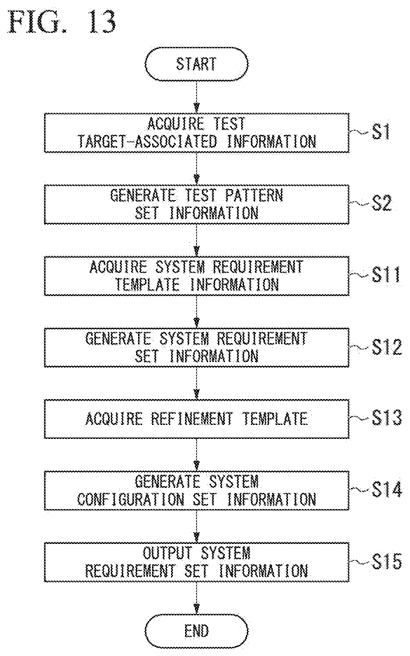

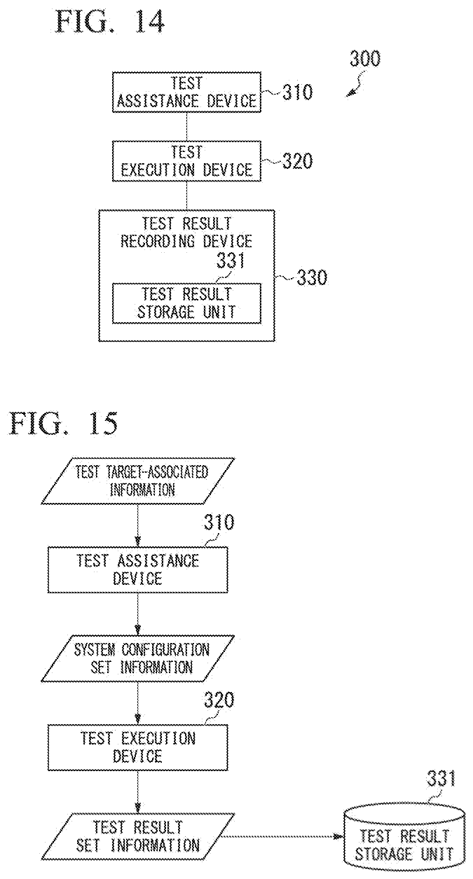

FIG. 14 is a schematic block diagram indicating an example of the structure of a test assistance system according to a third embodiment.

In the structure indicated in FIG. 14, the test assistance system 300 comprises a test assistance device 310, a test execution device 320, and a test result recording device 330. The test result recording device 330 comprises a test result recording unit 331.

The test assistance device 310 and the test execution device 320 are capable of communicating. The test execution device 320 and the test result recording device 330 are capable of communicating. The test assistance device 200 may be used as the test assistance device 310. Alternatively, a test assistance device 100 comprising a refinement template storage unit 282 and a test environment refinement unit 293 may be used as the test assistance device 310.

The test assistance device 310, the test execution device 320, and the test result recording device 330 may be configured as a single device. For example, the functions of the test assistance device 310, the test execution device 320, and the test result recording device 330 may be executed by the same computer. Alternatively, any two among the test assistance device 310, the test execution device 320, and the test result recording device 330 may be configured as a single device.

FIG. 15 is a diagram indicating an example of the input and output of data in the test assistance system 300. The test assistance device 310 receives test target-associated information that is input and outputs a system configuration set.

The test execution device 320 receives a system configuration set that is input and outputs a test result set. Specifically, the test execution device 320 performs tests, for each system configuration included in a system configuration set, using systems based on those system configurations as test environments. The test execution device 320 organizes the test results in a test result set.

The test results mentioned here are information indicating the results of tests in each test environment. Specifically, the test results are information indicating the values in evaluation criteria in tests performed in each test environment.

The test result set is information including one or more test results.

The test result recording device 330 stores the test result set output by the test execution device 320 in the test result storage unit 331.

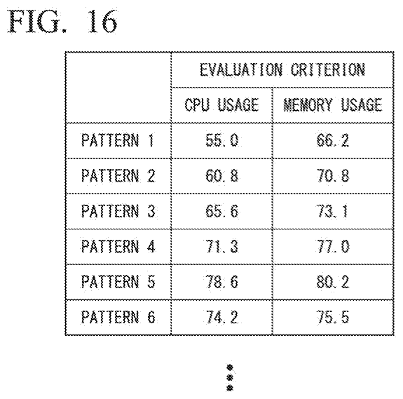

FIG. 16 is a diagram indicating an example of a test result set. FIG. 16 indicates an example in which the test execution device 320 displays an example of a test result set in table form. Alternatively, the test assistance device 310 or the test result recording device 330 may display the test result set.

The evaluation result set information is information indicating, for each test pattern, the values in the respective evaluation criteria obtained by the test execution device 320 performing a test.

The display example of the test result set indicated in FIG. 16 corresponds to an example in which a CPU usage value and a memory usage value are provided with embedded for each test pattern in the test results from the test execution device 320 in the display example of the test pattern set in FIG. 5. Therefore, in the example in FIG. 16, values of CPU usage and memory usage in servers running the application “app-face”, measured in evaluation tests for that application, are indicated as the evaluation results corresponding to the respective evaluation patterns.

The specific content and form of display of the evaluation results are not limited to those in the example indicated in FIG. 16.

### (Description of Operations)

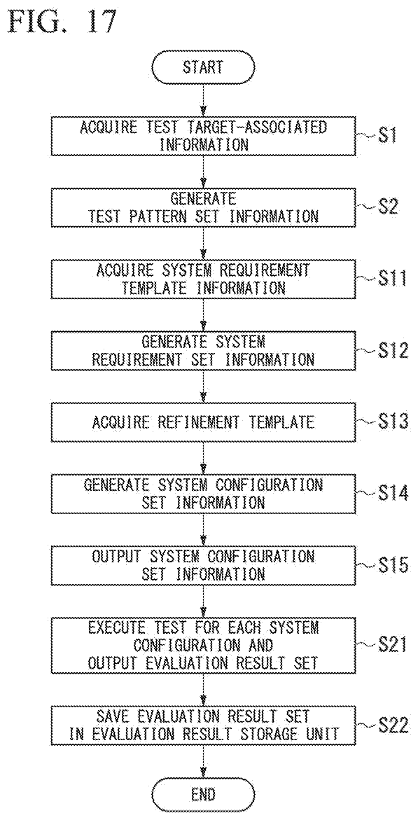

FIG. 17 is a flow chart indicating an example of the processing procedure performed by the test assistance system 300. FIG. 17 shows an example of the process in the case in which the test assistance device 200 is used as the test assistance device 310. Among the processing steps in FIG. 17, those that are similar to processing steps in FIG 13 will be assigned the same reference numbers (S1, S2, S11, S12, S13, S14, and S15) and detailed descriptions thereof will be omitted here.

Steps S1 to step S15 in FIG. 17 are similar to those in the case of FIG. 13. After step S15, the test execution device 320 receives, as an input, a system configuration set generated and output by the test assistance device 310, executes tests with each system configuration, and outputs an evaluation result set (step S21). The test execution device 320 may automatically construct systems as test environments based on the system configurations. Alternatively, the test execution device 320 may display system configurations, and a user may manually construct systems as test environments, such as by constructing systems in accordance with the system configurations.

The test execution device 320 performs tests with each system configuration and outputs the test results so as to be organized in a test result set.

Furthermore, the test result set output by the test execution device 320 may be acquired by the test result recording device 330 and may be stored in the test result storage unit 331 (step S22).

After step S22, the test assistance system 300 ends the process in FIG. 17.

Thus, in the test assistance system 300, the test assistance device 310 outputs a system configuration set based on test target-associated information indicating an evaluation axis set and an evaluation criterion set. Then, the test execution device 320 performs tests with each system configuration included in the system configuration set and outputs the test results as an evaluation result set. The test result recording device 330 acquires the evaluation result set output by the test execution device 320 and stores the evaluation result set in the test result storage unit 331.

### (Description of Effects)

Thus, with the test assistance system 300, in addition to the effects described for the test assistance device 100 and the effects described for the test assistance device 200, tests can be automatically or semi-automatically performed by means of the test execution device 320, and the evaluation results can be automatically stored by the test result recording device 330. Due to this feature, the burden on workers can be further reduced.

### Fourth Embodiment

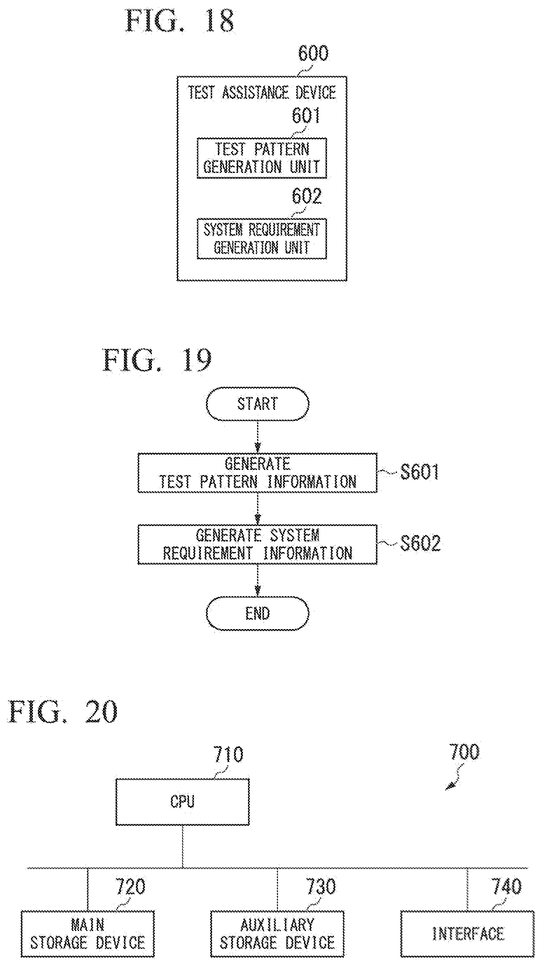

FIG. 18 is a diagram indicating an example of the structure of a test assistance device according to a fourth embodiment. In the structure shown in FIG. 18, the test assistance device 600 comprises a test pattern generation unit 601 and a system requirement generation unit 602.

With this structure, the test pattern generation unit 601 generates one or more test patterns in which the values of parameters in test target-associated information are determined based on test target-associated information indicating requirements, including parameters, for tests defined in accordance with a test target. The system requirement generation unit 602 generates system requirements for systems satisfying the requirements for tests indicated by test patterns.

The test pattern generation unit 601 corresponds to an example of a test pattern generation means. The system requirement generation unit 602 corresponds to an example of a system requirement generation means.

Thus, the test assistance device 600 generates a test pattern set, and a system requirement set corresponding thereto, from information regarding an evaluation axis set and an evaluation criterion set indicated in test target-associated information that has been input. As a result thereof, the test assistance device 600 can automatically or semi-automatically determine one or more system requirements (define requirements) as an exhaustive test environment set that is required in the process of testing a test target, such as a product. According to the test assistance device 600, due to this feature, systems satisfying the requirements for tests can be relatively easily generated.

### Fifth Embodiment

FIG. 19 is a flow chart indicating an example of the processing procedure in a test assistance method according to a fifth embodiment.

The process indicated in FIG. 19 includes steps of generating test patterns (step S601) and of generating system requirements (step S602).

The step of generating a test pattern (step S601) involves generating one or more test patterns in which the values of parameters in test target-associated information are determined based on test target-associated information indicating requirements, including parameters, for tests defined in accordance with the test target. The step of generating system requirements (step S602) involves generating system requirements for systems satisfying the requirements for the tests indicated by the test patterns.

In the process indicated in FIG. 19, a test pattern set, and a system requirement set corresponding thereto, are generated from an evaluation axis set and an evaluation criterion set indicated in test target-associated information that has been input. As a result thereof, in the process indicated in FIG. 19, one or more system requirements can be automatically or semi-automatically determined (requirements defined) as an exhaustive test environment set that is required in the process of testing a test target, such as a product. According to the process indicated in FIG. 19, systems satisfying the test requirements can be relatively easily generated due to this feature.

FIG. 20 is a schematic block diagram indicating the configuration of a computer according to at least one embodiment.

In the configuration indicated in FIG. 20, the computer 700 comprises a CPU 710, a main storage device 720, an auxiliary storage device 730, and an interface 740.

Any one or more among the above-mentioned test assistance device 100, the test assistance device 200, and the test assistance device 600 may be implemented in a computer 700. In that case, the operations in the above-mentioned processing units are stored in the auxiliary storage device 730 in the form of a program. The CPU 710 reads the program from the auxiliary storage device 730 and loads the program in the main storage device 720, then executes the above-described process in accordance with said program. Additionally, the CPU 710 retains, in the main storage device 720, a storage area corresponding to each of the above-mentioned storage units in accordance with the program.

In the case in which the test assistance device 100 is implemented in a computer 700, the operations of the control unit 190 and the parts thereof are stored in the auxiliary storage device 730 in the form of a program. The CPU 710 reads the program from the auxiliary storage device 730, loads the program in the main storage device 720, and executes the above-mentioned process in accordance with the program.

Additionally, the CPU 710 retains, in the main storage device 720, a storage area corresponding to the storage unit 180 in accordance with the program.

The communication by the communication unit 110 is performed by the interface 740 having a communication function and communicating in accordance with control by the CPU 710.

The display by the display unit 120 is performed by the interface 740 comprising a display screen and displaying various images in accordance with control by the CPU 710. The receiving of user operations by the operation input unit 130 is performed by the interface 740 comprising an input device, receiving user operations and outputting signals indicating the received user operations to the CPU 710.

In the case in which the test assistance device 200 is implemented in a computer 700, the operations of the control unit 290 and the parts thereof are stored in the auxiliary storage device 730 in the form of a program. The CPU 710 reads the program from the auxiliary storage device 730, loads the program in the main storage device 720, and executes the above-mentioned process in accordance with the program.

Additionally, the CPU 710 retains, in the main storage device 720, a storage area corresponding to the storage unit 280 and the parts thereof in accordance with the program.

The communication by the communication unit 110 is performed by the interface 740 having a communication function and communicating in accordance with control by the CPU 710.

The display by the display unit 120 is performed by the interface 740 comprising a display screen and displaying various images in accordance with control by the CPU 710. The receiving of user operations by the operation input unit 130 is performed by the interface 740 comprising an input device, receiving user operations and outputting signals indicating the received user operations to the CPU 710.

In the case in which the test assistance device 600 is implemented in a computer 700, the operations of the test pattern generation unit 601 and the system requirement generation unit 602 are stored in the auxiliary storage device 730 in the form of a program. The CPU 710 reads the program from the auxiliary storage device 730, loads the program in the main storage device 720, and executes the above-mentioned process in accordance with the program.

A program for realizing all or some of the functions of the test assistance device 100, the test assistance device 200, and the test assistance device 600 may be recorded in a computer-readable recording medium, and the program recorded in this recording medium may be read into a computer system and executed to perform the processes of the respective units. The “computer system” mentioned here includes an OS (Operating System) and hardware such as peripheral devices.

The “computer-readable recording medium” refers to portable media such as flexible discs, magneto-optic discs, ROMs (Read-Only Memory), and CD-ROMs (Compact Disc Read-Only Memory), and to storage devices such as hard disks internal to computer systems. Additionally, the above-mentioned program may be for realizing some of the aforementioned functions, and the aforementioned functions may be realized by being combined with a program already recorded in a computer system.

As above, technology for automatically designing a system has been proposed.

When performing a performance evaluation test or the like for an application program that runs on a system, there are cases in which systems (systems for evaluation tests) are used as test environments. In such cases, it is preferable for systems satisfying the requirements for tests to be able to be generated as easily as possible.

According to at least one exemplary embodiment, for example, systems that can satisfy the requirements for a test can be relatively easily generated.

While the present embodiments have been described in detail by referring to the drawings, the specific configuration is not limited to these embodiments, and design modifications and the like within a range not departing from the spirit of these embodiments are also included.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A test assistance device comprising:
at least one memory configured to store instructions; and
at least one processor configured to execute the instructions to;
generate one or more of a test pattern in which a value of a parameter in test target-associated information is determined based on the test target-associated information indicating, so as to include the parameter, a requirement for a test defined in accordance with a test target, and
generate a system requirement for a system satisfying the requirement for the test indicated by the test pattern.

2. The test assistance device according to claim 1, wherein the test target-associated information includes an evaluation axis set indicating, so as to be selectable including the parameter, a requirement for a test environment for the test, and an evaluation criterion set indicating an evaluation target criterion in the test.

3. The test assistance device according to claim 1, wherein the at least one processor is configured to execute the instructions to generate one or more of the system requirement by determining a value of the parameter in a system requirement template in which some system requirements among system requirements are indicated by the parameter.

4. The test assistance device according to claim 1, wherein the at least one processor is further configured to execute the instructions to generate a system configuration satisfying the system requirement by refining the system requirement.

5. The test assistance device according to claim 4, wherein the at least one processor is configured to execute the instructions to generate the system configuration by repeated partial refinement of the system requirement.

6. A test assistance method comprising:
generating one or more of a test pattern in which a value of a parameter in test target-associated information is determined based on the test target-associated information indicating, so as to include the parameter, a requirement for a test defined in accordance with a test target, and
generating a system requirement for a system satisfying the requirement for the test indicated by the test pattern.

7. A non-transitory computer-readable storage medium storing a program that causes a computer to execute processes, the processes comprising:
generating one or more of a test pattern in which a value of a parameter in test target-associated information is determined based on the test target-associated information indicating, so as to include the parameter, a requirement for a test defined in accordance with a test target, and
generating a system requirement for a system satisfying the requirement for the test indicated by the test pattern.
